(19) United States
(12) Patent Application Publication
(10) Pub. No.: US 2012/0120478 A1
(43) Pub. Date: May 17, 2012

(54) ELECTRO-OPTICAL DEVICES BASED ON THE VARIATION IN THE INDEX OR ABSORPTION IN THE ISB TRANSITIONS

(75) Inventors: François Julien, Gometz La Ville (FR); Anatole Lupu, Fontainebleau (FR); Maria Tchernycheva, Orsay (FR); Laurent Nevou, Bezons (FR)

(73) Assignees: CENTRE NATIONAL DE LA RECHERCHE SCIENTIFIQUE, Paris (FR); UNIVERSITE PARIS-SUD 11, Orsay (FR)

(21) Appl. No.: 13/387,035

(22) PCT Filed: Jul. 30, 2010
(86) PCT No.: PCT/FR2010/051636

§ 371 Date: Jan. 25, 2012

(30) Foreign Application Priority Data
Jul. 30, 2009 (FR) 0955365

(51) Int. Cl. G02F 1/017; H01L 33/04; H01L 31/0352; B82B 3/00; B82Y 20/00

(52) U.S. Cl. 359/279; 257/14; 438/47; 438/94; 359/245; 257/E33.005; 257/E31.033; 977/773; 977/932; 977/840; 977/759

(57) ABSTRACT

Electro-optical components are disclosed having intersubband transitions by quantum confinement between two Group III nitride elements, typically by means of GaN/AlN. Related devices or systems are also disclosed including such components, as well as to a method for manufacturing such a component. Such a component includes at least one active area that includes at least two so-called outer barrier layers surrounding one or more N-doped quantum well structures, and said quantum well structure(s) are each surrounded by two barrier areas that are unintentionally doped at a thickness of at least five monoatomic layers.

The present invention relates to electro-optic components with intersubband transition by quantum confinement between two materials of the nitride of group III elements type.

It furthermore relates to devices or systems that include such components and to a method for manufacturing such a component.

### TECHNICAL FIELD

The invention lies in the field of optoelectronics and photonics, in particular for applications in the fields of optical telecommunications and of optical cross-connects in integrated circuits.

The field of optoelectronics comprises different types of components that process or generate light, for example in order to emit light signals intended to measure a quantity, as in interferometry, or, as in the field of telecommunications, in order to communicate via signals comprising modulated light transmitted in optical fibres.

When a system uses both electrical signals and signals based on light, electronic-optical conversion components are needed.

For example, an electro-optic modulator is an element that allows data to be transferred from an electrical signal to an optical wave, for example in order to convert digital data in electronic form into a digital optical signal which will be carried in an optical fibre for long-distance transmission. Other types of emitters can take the form of a conventional (non-coherent) diode or of a laser diode, for example in order to act as light source.

Other optoelectronic components can also be optical filters the wavelength of which can be tuned by electrical control in order to separate certain wavelengths or extract a channel from a multi-band transmission, devices for optical routing that can be reconfigured by electrical control, or photodetectors for example for converting optical signals into electronic signals in a reception or retransmission system.

### STATE OF THE ART

In the field of optoelectronics, it is known to use structures with nanometric dimensions that combine semiconductors, in particular based on group III and group V elements, to form quantum structures that correspond to transitions in the energy level of the electrons interacting with the light wavelengths used.

These quantum structures can have different forms, such as two-dimensional layers of quantum thickness forming quantum wells, alternating with two-dimensional layers forming barrier layers. Structures including quantum “boxes”, for example with a substantially cylindrical shape, or even in the form of nanowires embedded within a material forming a barrier, are also used.

It should be noted that different types of optoelectronic components sometimes use similar quantum structures and materials, and that the same technology thus allows the production of several types of components by different organization of the location of the active region, for example in relation to electrodes or in relation to waveguide(s).

InP—Telecommunications (NIR)

In the field of telecommunications, the wavelengths used are those in the near-infrared (NIR) range, and more particularly of the order of 800 nm to 1600 nm, typically 1.55 μm.

In particular in the field of telecommunications, it is known to use material pairs such as InGaAsP to form the quantum structures, for example layers forming quantum wells (QWs), and InAlAs or InP for the barrier structures. The material forming the quantum well is chosen for its forbidden band, which is narrower than that of the material forming a barrier.

These materials are used for example to produce bipolar electro-optic modulators (i.e. with two types of carrier: electrons and holes) with interband transition operating by absorption. Such a modulator comprises an active region comprising one or more quantum structures. When a potential difference is applied to the active region, there is a change in the optical characteristics of this active region, in this case in the form of a variation in the light absorption.

By controlling this potential difference using an electronic signal and by injecting a steady light provided by a source into this active region, it is thus possible to modulate the intensity of the light leaving the component and thus produce an electro-optic modulator.

By positioning this active region through an optical signal, it is also possible to produce an electrically controlled filter.

In the current state of the art, this type of component makes it possible to provide intensity contrasts starting from 10 dB, which is the minimum for telecommunications applications. It is, however, useful to improve this contrast, for example in order to facilitate the decoding of the signal, but also in order to be able to reduce the size of the components. The total contrast obtained depends on the length over which the modulation is carried out.

Moreover, this type of component allows a full width at half maximum (FWHM) of the order of 50 meV with a wavelength of 1.3 to 1.55 μm. This FWHM value gives a wavelength ratio Δλ/λ=5%, which directly influences the “chirp” and therefore the quality of the separation between several frequency channels within a single waveguide.

An electro-optic modulator can also operate by phase variation: in a configuration where the application of voltage produces a change in the refraction of the active region, and therefore in the transmission speed of the light. By injecting a steady signal into this active region, it is thus possible to modulate its phase by controlling the potential difference. Such a phase modulator can for example be incorporated in an interferometer in order to provide a phase modulation, for example a ring interferometer or a Mach-Zehnder type interferometer.

Currently, this type of component allows a variation in the refractive index of the order of 10⁻³ (0.001).

Starting from these materials, unipolar modulators with intersubband (ISB) transition have also been produced, but these only operate by absorption, and in wavelengths that are of little use for telecommunications applications, for example λ=10 μm. In fact, in ISB devices based on InGaAs/AlInAs-on-InP or GaAs/AlGaAs, the minimum wavelength is limited to λ=3.5 μm and λ=8 μm respectively.

GaN—Medium Infrared (MIR)

In other wavelength regions, of the order of 1 μm to 20 μm, it has been proposed to use nitrides, and in particular the material GaN, to produce unipolar components with intersubband (ISB) transition.

The document U.S. Pat. No. 6,593,589 describes in particular a unipolar ISB modulator operating by absorption around 5.2 μm, using the QW-BL (for “Quantum Well—Barrier Layer”) pairs: GaN—AlN or GaN—InN or InGaN—GaN. It describes layers forming quantum wells with a thickness of 4 to 5 nm. Such components are used for example in broadcasting or aerial sensing, in order to take advantage of atmospheric transparency windows at wavelengths of 3-5 μm and 8-12 μm.

The proposed configurations comprise one or two quantum wells, which are separated by two thin barriers chosen so that they can be penetrated by tunneling.

More recent works have developed the use of GaN for unipolar components with ISB in wavelengths of 1 to 2.4 μm for a potential difference of 30V. It is useful to be able to use voltages that are as low as possible, for example in order to be compatible with the supply voltages commonly used in numerous electronic systems, often 12V, or even 10V and above all 3V.

Thus, Nevou et al. 2007 (Appl. Phys. Lett. 90, 223511, 2007) and Kheirodin et al. 2008 (IEEE Photon. Technol. Lett., vol. 20, no. 9, pp. 1041-1135 May 1, 2008) describe an improvement in performance by using an active region of twenty periods each comprising one coupled quantum well (CQW), itself formed by flat layers stacked up within a flat active region, with the QW-BL material pair made of GaN—AlN.

This coupled quantum well is constituted by a quantum well layer, called a reservoir, with a thickness of 3 nm, followed by a barrier layer thin enough to be penetrated by tunneling, with a thickness of 1 nm, followed by a layer forming a narrow quantum well with a thickness of 1 nm.

These works stress the speed performance supplied by the ISB transition. Kheirodin et al. state that the time it takes for the electron to pass, by tunneling, from one well to the other is a limit on the intrinsic speed of the modulator, and propose to improve this feature by reducing the dimensions of the active region of the modulator, for example by inserting it directly into the waveguide.

These technologies have a certain number of drawbacks, or it would be useful to improve them, for example as regards performance, simplicity and flexibility of engineering or compactness.

In addition, the reduction in the dimensions of the active region involves a reduction in the length of interaction, which can be detrimental to other performances, for example as regards intensity contrast.

Moreover, the development of equipment and networks for telecommunications makes all of the available improvements useful and interesting, in particular as regards performance, for example in terms of speed or spectral contrast or specificity or frequency stability, as well as with regard to compactness, simplicity and freedom of design and installation and production.

A purpose of the invention is to provide a technology that overcomes all or some of the drawbacks of the state of the art, and allows all or some of these improvements.

### DISCLOSURE OF THE INVENTION

The invention proposes an electro-optic component with intersubband transition by quantum confinement between two materials of the nitride of group III elements type. According to the invention, this component comprises at least one active region including at least two so-called outer barrier layers surrounding one or more “N”-doped quantum structures.

In all embodiments, this or these quantum structures are each surrounded by two unintentionally doped barrier areas with a thickness sufficient to prevent the passage of electrons by tunneling, in particular with a minimum thickness of more than four monoatomic layers, i.e. at least five monoatomic layers, or even at least six or eight monoatomic thicknesses.

In the case of a single quantum structure, the latter is surrounded by the two outer barrier layers, which are unintentionally doped and have this minimum thickness.

In the case where a single active region comprises several quantum structures, at least two (and advantageously all) successive quantum structures are all “N”-doped and are separated in pairs by an unintentionally doped barrier area implementing this minimum thickness.

The thickness of the outer barriers depends on the design of the entire component and in particular on the composition of the confinement layers. Their thickness of more than four monolayers can also be significantly greater, and influences the range of operating voltage for the device.

According to a non-compulsory feature, the barrier layers for separating quantum structures can be of equal thickness, to within one or two monoatomic thicknesses.

According to another non-compulsory feature, these successive quantum structures have an identical thickness, to within one or two monoatomic thicknesses.

In a particular type of embodiment, the component according to the invention comprises at least one active region including a plurality of successive quantum structures separated in pairs by an unintentionally doped barrier area, with a thickness sufficient to prevent the passage of electrons by tunneling, in particular with a thickness of at least five monoatomic layers.

Several quantum structures are desirable for example in order to increase the absorption in the absorbing state and the compactness of the device. Everything depends on the performance desired by the designer of the component, for example in the compromise between simplicity and cost of manufacture on the one hand and performance and/or compactness of the component on the other hand.

Advantageously, in the component according to the invention, the quantum structures comprise, for the most part, gallium nitride and the barrier areas comprise, for the most part, aluminium nitride or AlGaN.

These materials are particularly well-suited to the implementation of the invention, for example due to the discontinuity of potential in the conduction band ΔEc=1.75 eV for GaN/AlN, and owing to the current technical capabilities which, since at least 2006, have made it possible to produce structures with layers accurate to within one or two monoatomic layers, and with a thickness that can be reduced to three monoatomic layers.

In the case of a telecommunications type application, the thickness of the quantum structures is determined in order to tune this component to a wavelength comprised between 1.0 μm and 1.7 μm.

A preferred embodiment of the invention proposes such a component arranged according to an architecture producing an electro-optic modulator. Such a modulator can be arranged in order to operate by absorption, for example in order to optimize the contrast obtained as a priority.

It can also be arranged in order to operate by modulation of the refractive index, for example in order to give priority to the phase variation.

In other embodiments, the active region architecture according to the invention can also be used in a component arranged according to an architecture producing in particular:
a charge-transfer modulator, or
a photodetector, for example a quantum cascade photodetector, or
an electro-optic emitter, or
an electro-optic switch,
or an optical filter with an electrically controlled band, or
a combination of these types of functions.

The field of application of the invention is potentially very broad. In addition to the conversion components used for example in telecommunications, the invention also applies to components or devices such as tunable filters, reconfigurable optical routing and optical sensors for chemistry or biology, and other applications making use of the variation in absorption or index.

It is possible for example to produce a switch by inserting the active region within a waveguide or a beam which it is desired to interrupt or allow.

Moreover, it is possible to envisage using this type of active region to produce a filter, the filtering wavelength of which is controlled electrically, by regulating the potential difference applied to the active region.

In particular, the quantum structures can be essentially two-dimensional, in particular flat, layers forming quantum wells. Each of these quantum wells is surrounded on each side by at least one two-dimensional, in particular flat, layer forming a barrier.

Advantageously, such a component is arranged in order to operate with a polarization of the light perpendicular to the plane of the layers forming the quantum structures, or to a surface tangential to these layers.

In a typical embodiment, an electro-optic modulator according to the invention comprises an active region including three successive uncoupled quantum wells.

For example for a component tuned to frequencies of telecommunications types and more precisely in the spectral region λ=1.3 μm to λ=1.55 μm, the quantum wells are made of “N”-doped GaN and have a thickness of 4 to 6 monoatomic layers (i.e. approximately 1 to 1.5 nm). These quantum well layers are then separated from each other by barrier layers made of unintentionally doped AlN having a thickness of five or more monoatomic layers.

According to a feature, the active region of such a component is surrounded by two confinement layers with a certain thickness, for example of at least 0.4 micrometre, and is arranged in a portion in the form of a ridge or mesa forming a waveguide by variation or by jump in index.

These confinement layers are for example made of “n”-doped Al_{0.5}Ga_{0.5}N. They ensure the optical confinement of the guided mode by a jump in index and are also used to form the electrical contacts, thus also playing the role of contact layer.

One of these two confinement (or contact) layers carries, on its surface, one or more electrodes with a first polarity, for example a single electrode on the majority of its outer surface, on the side opposite the active region.

The other confinement (or contact) layer carries, on its surface, one or more electrodes with a second polarity, for example two electrodes with the same polarity carried on the surface of two shoulders of the confinement layer extending from each side of the axis of the waveguide.

The waveguide formed by the confinement layers and the active region can for example be arranged on at least one buffer layer made of semi-conductor, for example a nitride of a group III element such as AlN. This buffer layer is itself carried by a substrate, for example sapphire.

Other known configurations can also be used, using for example a conductive substrate carrying an electrode with the second polarity on its surface on the side opposite the waveguide.

According to another aspect, the invention proposes a device or system comprising at least one component such as disclosed here.

It also proposes a method for manufacturing an optoelectronic component or device or system, comprising production steps using manufacturing techniques known to a person skilled in the art chosen, arranged and combined in order to produce a component such as disclosed.

### Advantages Provided

The component according to the invention in general, and the modulator in particular, has a great many advantages, for example as regards performance but also due to a simplification of the engineering and a wide field of use.

These advantages include in particular:

Better intensity contrast: The advantages provided by the invention include in particular an improvement in the intensity contrast, obtained at ambient temperature at approximately 14 dB for a potential difference of 7V and at approximately 10 dB for 5V, in a spectral band ranging from 1.2 μm to 1.6 μm. By way of comparison, the value of 14 dB allows a detection error rate of the order of 10⁻¹⁵ while the value of 12 dB of the state of the art gave an error rate of the order of 10⁻⁹, i.e. an improvement by a factor of 10 to the power six.

Better index contrast: In the case of a modulator operating in phase modulation, the variation in refraction obtained is of the order of Δn=10⁻² (0.01), which constitutes an improvement by a factor of ten.

Improvement in the modulation “chirp”: Moreover an enhancement of the index variation near to the absorption line is obtained, which makes the operation more stable, in particular by reducing the chirp during the modulation.

Larger spectral width of the absorption line: The spectral specificity obtained is improved to approximately 100 meV for a transition of 0.9 eV i.e. λ=1.38 μm, which results in a ratio of Δλ/λ of approximately 25%. This spectral width is in particular much greater compared with electro-absorption modulators based on the Franz-Keldysh effect or confined Stark effect. This allows better performance or an easier downstream processing, for example as regards the separation of the channels.

Simplified adjustment of the position of the absorption line: the simplified structure of the uncoupled quantum wells allows a greater freedom of design of the architecture of the active region, and therefore it is easier to adapt to specifications. The adjustment of the spectral position of the absorption line is carried out by controlling the thickness of the structures forming quantum wells. As each one comprises only a single continuous region (uncoupled wells) and not two coupled regions as in the state of the art (coupled wells), control of the thickness of this region is easier and has fewer additional repercussions on other operating features of the assembly.

For a modulator or a detector or an emitter, it is thus possible to more easily tune the structure of the component to the wavelength to be processed. For the pair GaN/AlN, the ISB transitions can be tuned in the range 1.3 μm-1.55 μm by using GaN thicknesses of 4 to 6 monoatomic layers, i.e. 1 to 1.5 nm.

Low sensitivity to temperature of the position of the absorption line, which allows an operation that is more stable and easier to manage.

Engineering of the refractive index: this index can be adjusted by controlling the composition and the thickness of the layers of the active region, in particular for the quantum structures.

Wide spectral region of transparency: making it possible to use or process luminous fluxes ranging from the ultraviolet to the near-infrared spectrum.

Control of the confinement of the optical mode: carried out by index contrast, which provides performance and simplicity of engineering for example for the design of the circuits.

Value of the refractive index: situated around 2.2, it makes it possible to produce very compact components. For example, it can involve the possibility of manufacturing strips with a large number of pixels, for example for imaging.

Electrical features: the invention allows a small thermal effect, of the order of 10⁻⁵ K⁻¹ for Δn/ΔT. It also allows a reduction in the resistivity, allowing the use of potential differences of the order of 12V or 10V, or even 5V or 3V. This allows an easier and more economical integration into numerous electronic systems, which are often supplied with direct voltage lower than these values.

Moreover, the invention enables the component to exhibit satisfactory behaviour mechanically and with respect to temperature, optical flux and ionizing radiation.

Moreover, the materials used are of a biocompatible nature, and are not very harmful as regards respect for the environment.

The advantages mentioned here are also added to the advantages already known for the use of ISB transition.

Intrinsic speed: This is for example an ultra-fast operation obtained, among other things, by the ISB relaxation rate via LO phonons: at about 0.15 ps to 0.4 ps, making it possible to envisage for example components of the all-optical switch type operating in the Tbit/s rate.

All or some of these advantages also apply to numerous electro-optic components using interband transitions other than the modulator, for example those mentioned above.

### Other Types of Components

It should be noted that structures of layers of GaN forming quantum wells are used in different components and operating according to a different mechanism, in order to produce all-optical switches or commutators, as described in documents JP 2005 215395 and JP 2001 108950.

Thus the document JP 2005 215395 describes an optical conductor carrying out an all-optical switch function, and not an electro-optic switch function. This all-optical switch comprises a stack of semiconductor nitride layers forming quantum wells, with the purpose of operating with a lower switching energy.

The stack of layers is in the form of a ridge or mesa, with a width that decreases in stages, forming an optical waveguide. This ridge receives a light input through an input end and emits, through an output end, a light controlled by intersubband transition and operating by saturable absorption under the action of the energy of the input light.

This type of component is typically used to produce an output optical signal from an input optical signal. This can for example involve regenerating the form of the signals within an optical conductor, or connecting two optical circuits to each other by a link of the “photonic cross-connect” (PXC) type, also called “transparent cross-connect” (OXC).

Various embodiments of the invention are provided for, integrating the different optional features disclosed here, according to all of their possible combinations.

Other characteristics and advantages of the invention will become apparent from the detailed description of an embodiment which is in no way imitative, and the attached drawings in which:

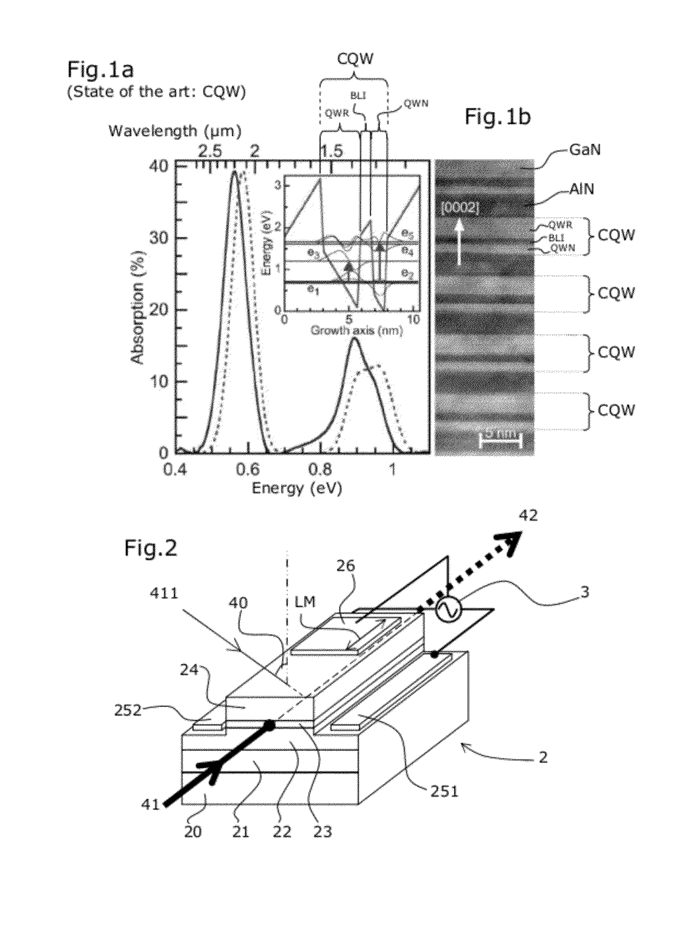

FIGS. 1a and b illustrate a state of the art using about twenty periods of coupled quantum well layers of GaN separated by barrier layers of AlN;

FIG. 2 is a diagram illustrating the principle of an electro-optic modulator in an embodiment of the invention, receiving a light source through the wafer or at Brewster's angle;

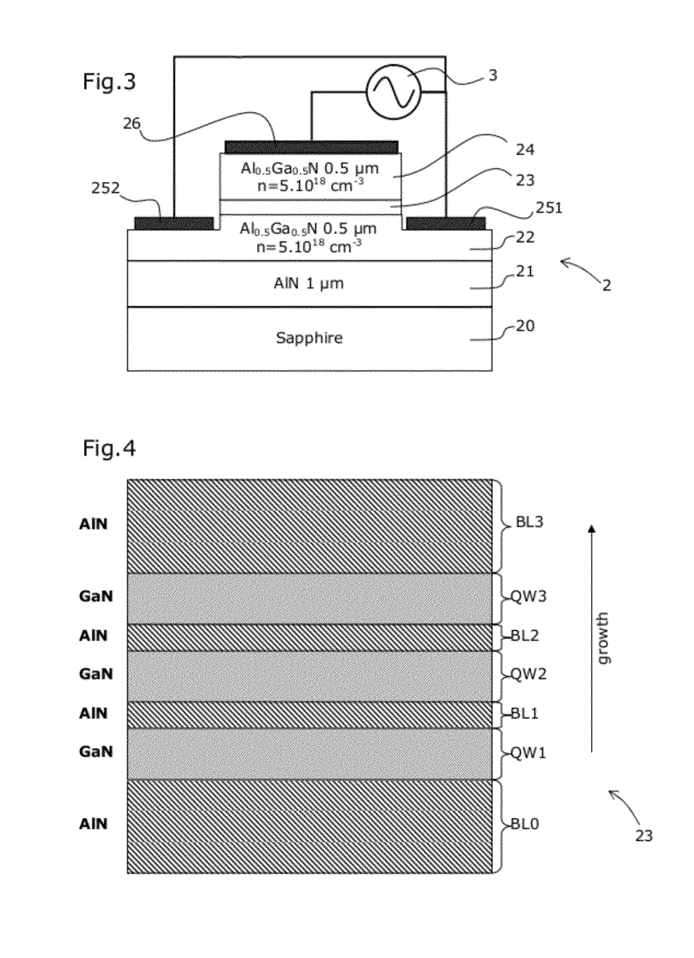

FIG. 3 is a sectional schematic diagram illustrating the architecture of the modulator of FIG. 2;

FIG. 4 is a sectional schematic diagram illustrating the architecture of the active region of the modulator of FIG. 2;

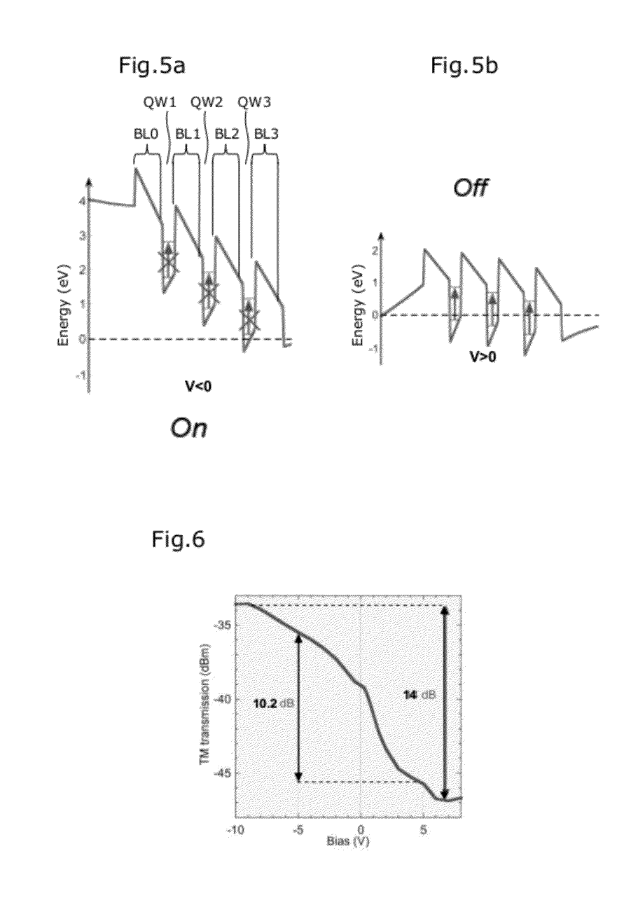

FIGS. 5a and b are operating diagrams illustrating the variation in energy depending on the thickness of the active region of FIG. 4,
FIG. 5a: with a negative potential difference, and
FIG. 5b: with a positive potential difference;

FIG. 6 is a curve illustrating the variation in the intensity contrast as a function of the potential difference applied to the electrodes of the modulator of FIG. 2, in wafer illumination mode.

### DETAILED DESCRIPTION OF THE FIGURES

FIGS. 1a and b illustrate a state of the art described by Nevou et al. 2007 (Appl. Phys. Lett. 90, 223511, 2007) and Kheirodin et al. 2008 (IEEE Photon. Technol. Lett., vol. 20, no. 9, pp. 1041-1135 May 1, 2008). This publication shows a modulator using, in an active region, about twenty periods of coupled quantum well layers of GaN separated by barrier layers of AlN.

FIG. 1b is a sectional photo of a portion of the active region, which shows approximately five pairs of coupled wells CQW separated by 2.7-nm barrier layers of AlN (in dark grey). Each of these coupled wells CQW comprises a quantum well reservoir QWR with a thickness of 3 nm and an n-doped quantum well QWN with a thickness of 1 nm, both made of GaN (in light grey). Within each of these pairs of coupled wells CQW, the two regions made of GaN are separated by a coupling barrier BLI with a thickness of 1 nm made of AlN (in dark grey).

FIG. 1a is a graph representing the obtained absorption (scale on the left) as a function of the wavelength (scale at the bottom) or of the energy (scale at the top) of the light used.

The insert inside this FIG. 1a represents the operating mode of a pair of these coupled wells CQW, and the variations in energy (scale on the left) as a function of its structure transverse to the different layers (scale at the bottom). The horizontal distribution of the variations as saw teeth thus corresponds to the structure of the different layers of this pair of coupled wells CQW, i.e. in succession from left to right: QWR, then BLI, then QWN.

FIG. 2 and FIG. 3 are diagrams schematically representing the architecture of an electro-optic modulator in an embodiment example of the invention.

The operating principle of such a modulator 2 is illustrated in FIG. 2. This modulator comprises an active region 23 forming a waveguide between two confinement regions 22 and 24. This active region is controlled by at least one electrode 26 with a first polarity and at least one electrode (here divided into two elements 251 and 252) with a second polarity controlled by an electrical control device 3 by varying the voltage.

In one configuration, the active region 23 receives a luminous flux 41 through the wafer. This flux is guided inside the active region and leaves it from the other side as an output luminous flux 42.

In another configuration, a luminous flux 411 penetrates through the upper confinement layer 24 at Brewster's angle 410, and passes through it up to the active region 23. This flux is then guided through this active region and leaves it as an output luminous flux 42.

Under the effect of the potential difference between the electrodes 251, 252 on the one hand and 26 on the other hand, the active region 24 has a light absorption which varies as a function of the electrical control 3 over a certain modulation length LM. The luminous flux passing through it therefore leaves it with an intensity 42 modulated according to the electrical control 3.

In a modulator configuration, with an electrical control 3 receiving an electrical input signal, a luminous flux 42 modulated as a function of this same electrical control signal is obtained at the outlet. This modulation can be applied to an input luminous flux 41 originating from a steady source such as a laser, or can be applied to a luminous flux 41, itself already comprising a signal.

It is also possible to use the electrical control 3 as an on-off control of an absorption of the input luminous flux 41, and thus to obtain an attenuation or even a blocking of this input flux 41, producing a switch or a controlled filter for this input flux 41.

FIG. 3 and FIG. 4 more precisely represent this example of the architecture of the modulator 2.

This architecture is obtained by successive growth, according to methods known to a person skilled in the art, or according to those mentioned in the documents listed previously.

A 1-μm buffer layer 21 of AlN is grown on a substrate 20, for example made of sapphire.

Then a first confinement layer 22, or contact layer, “n”-doped, for example to 5.10¹⁸ cm⁻³, for example one with a thickness of 0.5 μm of Al_{0.5}Ga_{0.5}N, is grown.

The active region 23, represented in more detail in FIG. 4, is then produced on a portion of this first confinement layer 22, for example in a central portion.

One or more conductive, or even metallic, layers 251 and 252 forming an electrode with one polarity is deposited on another portion of the first confinement layer 22, for example on the two sides around the active region 22.

A second confinement layer 24, or contact layer, “n”-doped, for example to 5.10¹⁸ cm⁻³, for example one with a thickness of 0.5 μm of Al_{0.5}Ga_{0.5}N, is then grown on the active region 23.

At least one conductive, or even metallic, layer 26 forming an electrode with the other polarity is deposited on the second confinement layer 24.

FIG. 4 represents in more detail the structure, in vertical cross-section, of the active region 23. In order to produce this active region, the following are grown in succession:
a first outer barrier layer BL0 of AlN of at least approximately 3 nm;
several quantum layers, here three layers forming quantum wells QW1, QW2 and QW3 made of GaN of equal thicknesses, each with a thickness of 4 to 6 monoatomic layers, i.e. approximately 1 to 1.5 nm;
between the quantum well layers QW1, QW2 and QW3, barrier layers are grown after each one and before the next, here two barrier layers BL1 and BL2, made of AlN with a thickness of typically 3 nm;
a second outer barrier layer BL3 of AlN of at least approximately 3 nm.

FIGS. 5a and b illustrate the operation of a modulator according to the invention, in the embodiment described above with three uncoupled quantum wells. The three saw tooth profiles towards the bottom are positioned at the sites of the layers QW1 to QW3 of GaN forming quantum wells, on the abscissa axis representing the dimension of the active region 23 transverse to the quantum QW and barrier BL layers.

FIG. 6 illustrates the variation in the intensity contrast obtained, as a function of the potential difference applied to the electrodes of the modulator described above, in wafer illumination mode.

It can be seen that the contrast obtained for a potential difference of +7V is 14 dB, which constitutes a useful performance compared with the state of the art. The contrast of 10.2 dB is a less good performance in absolute terms, but is obtained here with a lower potential difference of −5V, which makes it possible to produce a component requiring a lower voltage, for example with a supply of lower voltage. Thus, a good relationship between the performance and the engineering constraints as regards the electrical circuit is obtained. In particular, this potential difference of 5V is compatible with a supply voltage of 5V, which is an extremely common standard in the field of small electrical appliances as well as integrated components and circuits in general.

Of course, the invention is not limited to the examples which have just been described, and numerous adjustments can be made to these examples without exceeding the scope of the invention.

1. An electro-optic component with intersubband transition by quantum confinement between two materials of the nitride of group III elements type, comprising: at least one active region including at least two so-called outer barrier layers surrounding one or more “N”-doped quantum structures said quantum structure(s) are each surrounded by two unintentionally doped barrier areas with a thickness of at least five monoatomic layers.

2. The component according to claim 1, characterized in that it comprises at least one active region including a plurality of the successive quantum structures separated in pairs by an unintentionally doped barrier area, with a thickness sufficient to prevent the passage of electrons by tunneling, in particular with a thickness of at least five monoatomic layers.

3. The component according to claim 1, characterized in that the quantum structures comprise, for the most part, gallium nitride and the barrier areas comprise, for the most part, aluminium nitride and/or AlGaN.

4. The component—according to claim 1, characterized in that the thickness of the quantum structures is determined so as to tune said component to a wavelength of more than 1.0 μm, in particular between 1.0 μm and 1.7 μm.

5. The component according to claim 1, characterized in that it has an architecture producing an electro-optic absorption modulator.

6. The component according to claim 1, characterized in that it has an architecture producing an electro-optic phase variation modulator.

7. The component according to claim 1, characterized in that it has an architecture producing:
a charge-transfer modulator, or
a photodetector, for example a quantum cascade photodetector, or
an electro-optic emitter, or
an electro-optic switch,
or an optical filter with an electrically controlled band, or
a combination of these types of functions.

8. The component according to claim 1, characterized in that the quantum structures are two-dimensional layers forming quantum wells each surrounded by two-dimensional layers forming a barrier.

9. The component according to claim 1, characterized in that it is arranged so as to operate with a polarization of the light perpendicular to the plane of the layers forming the quantum structures.

10. The component according to claim 4, characterized in that the quantum wells are made of “N”-doped GaN and have a thickness of four to six monoatomic layers, and are separated by barrier layers made of unintentionally doped AlN having a thickness of more than four monoatomic layers.

11. The component according to claim 2, characterized in that the active region comprises three quantum wells.

12. The component according to claim 2, characterized in that the active region is surrounded by two confinement layers with a thickness of at least 0.4 micrometre, and is arranged in a portion in the form of a ridge or mesa forming a waveguide by index contrast.

13. A device or system comprising at least one component according to claim 1.

14. A method for manufacturing a component or device or system according to claim 1, comprising at least one step using the control of the thickness of the structures forming quantum wells in order to adjust the spectral position of the absorption line and/or the refractive index.

15. A method for manufacturing an optoelectronic component or device or system comprising the selected, defined and combined steps so as to produce a component according to claim 1.
